(19) United States
(12) Patent Application Publication
(10) Pub. No.: US 2017/0330827 A1
(43) Pub. Date: Nov. 16, 2017

(54) HYBRID EMBEDDED SURFACE MOUNT MODULE FORM FACTOR WITH SAME SIGNAL SOURCE SUBSET MAPPING

(71) Applicant: Digi International Inc., Minnetonka, MN (US)

(72) Inventors: Mike Oliver Rohrmoser, Hudson, WI (US); Sebastien Joseph Xavier Meyer, Turckheim (FR)

(21) Appl. No.: 15/376,458

(22) Filed: Dec. 12, 2016

Related U.S. Application Data
(60) Provisional application No. 62/335,494, filed on May 12, 2016.

(51) Int. Cl. H01L 23/498; H05K 1/02; H01L 23/552; H05K 1/11; H05K 1/18

(52) U.S. Cl. CPC H01L 23/49838; H05K 1/181; H05K 1/183; H01L 23/552; H05K 1/117; H05K 1/0224; H05K 2201/10159

(57) ABSTRACT

A surface mount module form factor comprises a substrate having a bottom surface, a top surface, and an outer periphery, with at least one electronic component mounted on the substrate, and a plurality of land grid array pads mounted on the bottom surface of the substrate. At least some of the land grid array pads are coupled to the at least one electronic component. A plurality of castellated edge pads are mounted around the outer periphery of the substrate, with at least some of the castellated edge pads coupled to the at least one electronic component. At least some of the land grid array pads are mapped to at least some of the castellated edge pads.

This application claims the benefit of priority to U.S. Provisional Application No. 62/335,494, filed on May 12, 2016, the disclosure of which is incorporated by reference.

### BACKGROUND

Various surface mount module form factors are commercially available. These form factors are typically based on either castellated edge pad patterns, or land grid array pad patterns. In such cases where both pad patterns are present, these are simply offering the different pads for mixed signal use, without pad subset mapping to the land grid array pads.

In one aspect, this disclosure is directed to addressing the problem of providing a unified surface mount (SMT) module platform decision for: a more complex but more versatile land grid array based module, vs. an easy-to-use but more limited castellated edge module.

### SUMMARY

A surface mount module form factor comprises a substrate having a bottom surface, a top surface, and an outer periphery, with at least one electronic component mounted on the substrate, and a plurality of land grid array pads mounted on the bottom surface of the substrate. At least some of the land grid array pads are coupled to the at least one electronic component. A plurality of castellated edge pads are mounted around the outer periphery of the substrate, with at least some of the castellated edge pads coupled to the at least one electronic component. At least some of the land grid array pads are mapped to at least some of the castellated edge pads.

### BRIEF DESCRIPTION OF THE DRAWINGS

Features of the present invention will become apparent to those skilled in the art from the following description with reference to the drawings. Understanding that the drawings depict only typical embodiments and are not therefore to be considered limiting in scope, the invention will be described with additional specificity and detail through the use of the accompanying drawings, in which:

FIG. 1 is a bottom view of a surface mount module form factor according to one embodiment;

FIG. 2 is a bottom view of a surface mount module form factor according to another embodiment;

FIG. 3 is a top view of the surface mount module form factor of FIG. 2;

FIG. 4 is a top view of the surface mount module form factor of FIG. 2, which includes a top shield; and

FIG. 5 is a block diagram of an embedded communication platform, which can be implemented with the surface mount module form factor of FIG. 2.

### DETAILED DESCRIPTION

In the following detailed description, embodiments are described in sufficient detail to enable those skilled in the art to practice the invention. It is to be understood that other embodiments may be utilized without departing from the scope of the invention. The following detailed description is, therefore, not to be taken in a limiting sense.

A hybrid embedded surface mount module form factor is disclosed, in which same signal source subset mapping is provided. The surface mount module form factor combines two distinct integration techniques, utilizing shared pinouts, to provide a low-profile and cost-effective platform for mounting various electronic components.

In one embodiment, the surface mount module form factor comprises one or more electronic components mounted on a substrate, a plurality of land grid array pads on the substrate, and a plurality of castellated edge pads around a periphery of the substrate. At least some of the land grid array pads are coupled to the electronic components, and at least some of the castellated edge pads are also coupled to the electronic components. In addition, at least some of the outer land grid array pads are directly mapped to at least some of the castellated edge pads.

The direct mapping of the outer land grid array pads to the castellated edge pads allows sharing of a common subset of signals from the same source, greatly simplifying implementation of the surface mount module form factor and common software platform support. This technique also delivers a universal form factor platform, without compromising time-to-market, design flexibility, optimized assembly cost, and overall cost of goods.

The present approach provides two distinct methods of integrating various electronic components, including single function, multi-function, or system-on-module components, in a common surface mount (SMT) module form factor. By providing both high density land grid array pads and castellated edge pads, the present form factor allows for direct attachment to a carrier printed circuit board (PCB) without any connectors, as well as selecting for the most cost-effective and fastest design and assembly method. In addition, the same module form factor platform can be used in a wide variety of designs and applications.

Embodiments using the present approach may offer a number of advantages, including: simplified manufacturing or assembly options across low and high volume builds; designs for fully automated component pick-and-place manufacturing; more cost-effective and lower carrier PCB layer count using castellated edge pads; and castellated edge pads allowing for manual placement (prototyping, etc.). In addition, the land grid array pads offer complete pinout for complex designs; the castellated edge pads offer exact same-source subset of pinout for simplified design integration; and the castellated edge pads are directly mapped to outer land grid array pads to deliver a subset of functionality.

Other benefits of the present approach include no board connector cost, and no board connector supply dependency; highly reliable low-profile surface mount assembly; one form factor platform suitable for a wide array of designs; an optional cavity for bottom module components that eliminate the need for a carrier PCB routing pattern; and unified software platform support regardless of the integration method used.

Further details of the various embodiments are described hereafter with reference to the drawings.

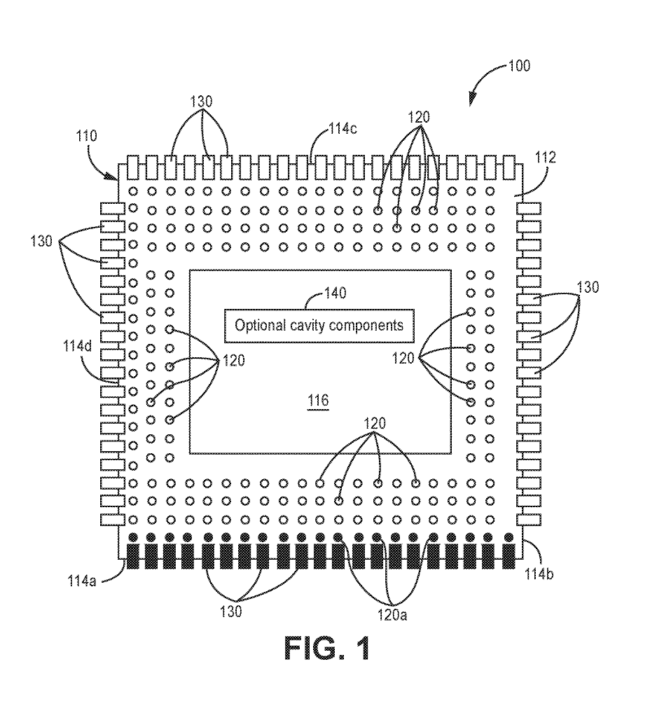

FIG. 1 illustrates a bottom view of a surface mount module form factor 100, according to one embodiment. The form factor 100 includes a substrate 110 having a bottom surface 112 with peripheral edge portions 114a-114d. A cavity 116 can be optionally located in a central area of bottom surface 112 and extends to the inside of substrate 110. Multiple land grid array pads 120 are mounted to bottom surface 112 and surround cavity 116 when present. A plurality of castellated edge pads 130 are mounted to edge portions 114a-114d and surround land grid array pads 120.

As shown in FIG. 1, each of castellated edge pads 130 along edge 114a can be respectively mapped to adjacent land grid array pads 120a. This provides an exact same-source subset of the land grid array pads.

The form factor 100 supports the optional placement of electronic components 140 in cavity 116, providing a flat configuration for bottom surface 112. This flat configuration eliminates the need for a routing pattern in a mating carrier PCB for form factor 100.

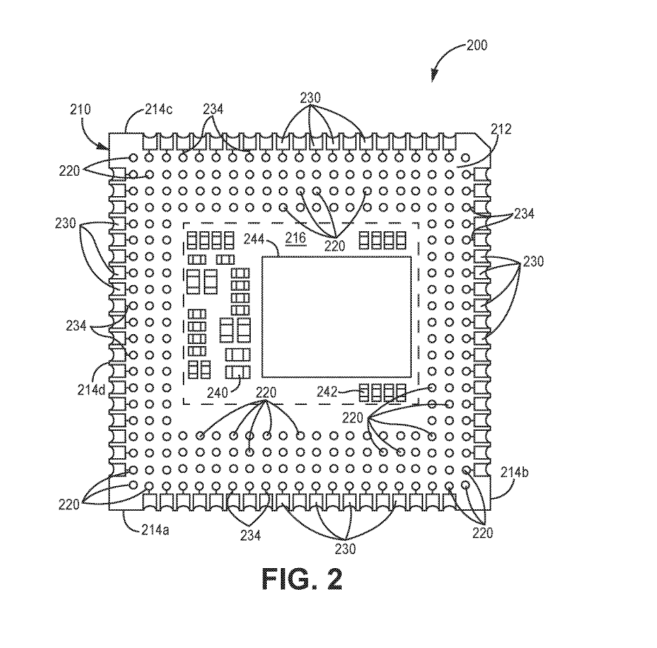

FIGS. 2-4 illustrate a surface mount module form factor 200 according to another embodiment.

As shown in the bottom view of FIG. 2, form factor 200 includes a substrate 210 having a bottom surface 212 and peripheral edge portions 214a-214d. A cavity 216 can be located in a central area of bottom surface 212 and extends to the inside of substrate 210. Multiple land grid array pads 220 are mounted to bottom surface 212 and surround cavity 216. A plurality of castellated edge pads 230 are mounted to edge portions 214a-214d and surround land grid array pads 220.

As depicted in FIG. 2, each of castellated edge pads 230 along edges 214a-214d can be respectively mapped to adjacent outer land grid array pads 220 with respective common pins 234. This provides an exact same-source subset of the land grid array pads.

The form factor 200 supports the placement of various electronic components 240, 242, 244 in cavity 216, providing a flat configuration for bottom surface 212. The electronic components can include memory devices, processors, communication devices, or the like.

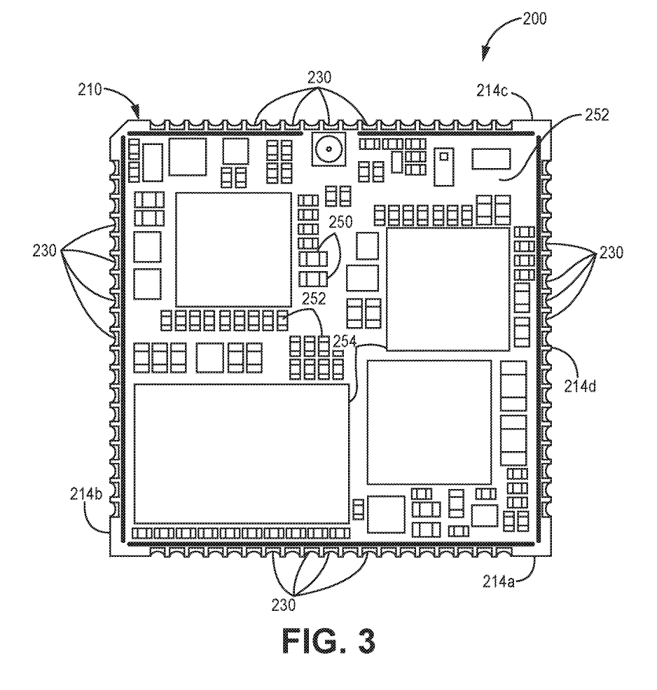

As shown in the top view of FIG. 3, substrate 210 of form factor 200 includes a top surface 252. The castellated edge pads 230 wrap around edge portions 214a-214d such that a portion of the castellated edge pads 230 are also mounted around a periphery of top surface 252.

The form factor 200 also supports the placement of various electronic components 250, 252, 254 on top surface 252. The electronic components can include processors, memory devices, communication devices, or the like.

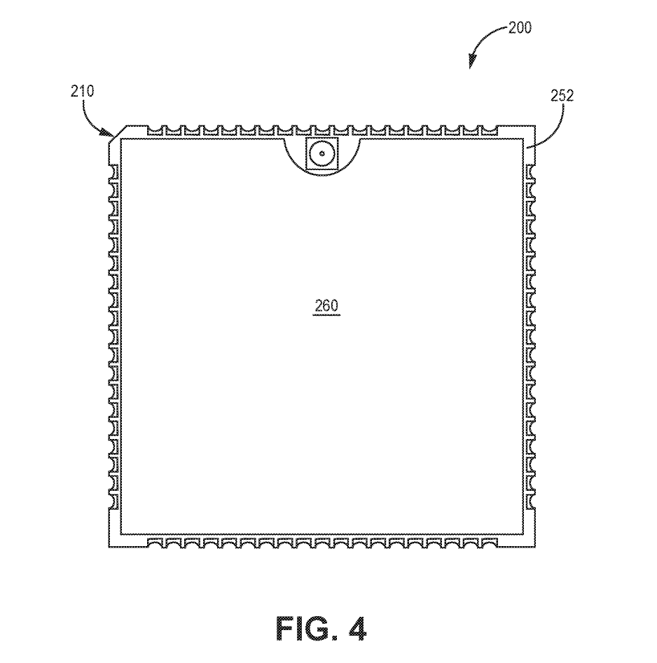

As depicted in the top view of FIG. 4, form factor 200 can include a top shield plate 260, which is mounted over top surface 252 of substrate 210. The top shield plate 260 provides protection for the electronic components on top surface 252. The top shield plate 260 can be composed of various protective materials.

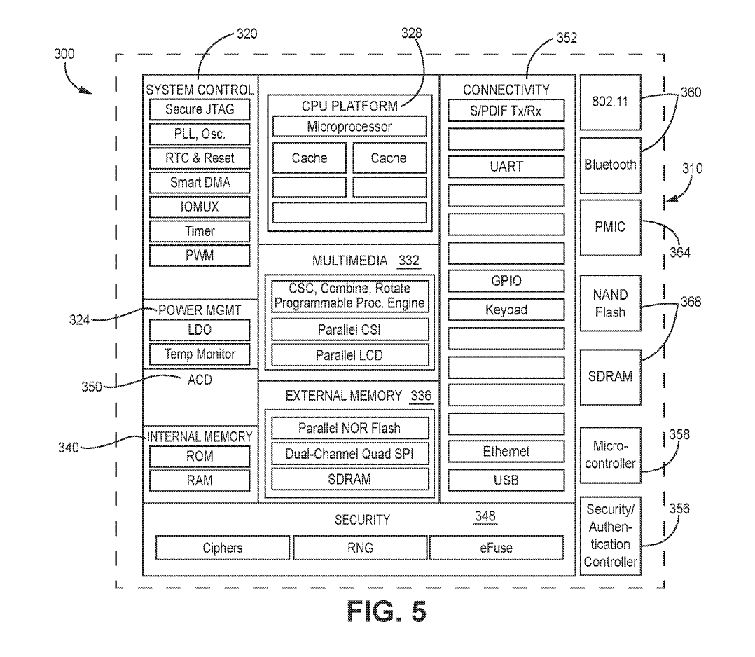

The techniques described herein can be implemented in an embedded system-on-module product, which employs the present surface mount module form factor. One example of such a product is illustrated in FIG. 5, which is a block diagram of a connected and secure, embedded communication platform 300. The communication platform 300 includes various electronic components that are mounted on a surface mount module form factor 310, which can have similar features as described above for form factor 200, for example.

The communication platform 300 can include a plurality of system control components 320, such as for secure JTAG, a phase lock loop (PLL), an oscillator, a real-time clock (RTC) and reset, smart direct memory access (DMA), IOMUX, timer, and pulse width modulation (PWM) circuit; power management components 324, such as low drop out (LDO) regulator, and a temperature monitor; a CPU platform 328 for a microprocessor and various processing components; multimedia components 332, such as CSC, combine, rotate, programmable, processing engine, parallel CSI, and parallel LCD; external memory components 336, such as NOR flash, dual-channel quad serial peripheral interface (SPI), and SDRAM; internal memory components 340, such as ROM and RAM; security components 348, such as ciphers, a random number generator (RNG), and eFuse; and address conflict detection (ACD) software 350. Additional components on communications platform 300 can include connectivity components 352, such as for a universal asynchronous receiver/transmitter (UART), general purpose input/output (GPIO), S/PDIF transmitter/receiver, USB, Ethernet, keypad, and the like; a security and authentication controller 356; a microcontroller 358; wireless communication components 360 such as for WiFi (802.11), Bluetooth, or the like; a power management integrated circuit (PMIC) 364; and additional memory components 368 such as NAND flash and SDRAM.

### Example Embodiments

Example 1 includes a surface mount module form factor, comprising: a substrate having a bottom surface, a top surface, and an outer periphery; at least one electronic component mounted on the substrate; a plurality of land grid array pads mounted on the bottom surface of the substrate, wherein at least some of the land grid array pads are coupled to the at least one electronic component; and a plurality of castellated edge pads mounted around the outer periphery of the substrate, wherein at least some of the castellated edge pads are coupled to the at least one electronic component; wherein at least some of the land grid array pads are mapped to at least some of the castellated edge pads.

Example 2 includes the surface mount module form factor of Example 1, wherein the at least one electronic component comprises at least one single function component.

Example 3 includes the surface mount module form factor of any of Examples 1-2, wherein the at least one electronic component comprises at least one multi-function component.

Example 4 includes the surface mount module form factor of any of Examples 1-3, wherein the at least one electronic component comprises at least one system-on-module component.

Example 5 includes the surface mount module form factor of any of Examples 1-4, wherein the at least one electronic component is mounted on the top surface of the substrate.

Example 6 includes the surface mount module form factor of any of Examples 1-5, further comprising a cavity in the bottom surface of the substrate, wherein the at least one electronic component is mounted inside of the cavity.

Example 7 includes the surface mount module form factor of Example 6, further comprising one or more additional electronic components mounted on the top surface of the substrate.

Example 8 includes the surface mount module form factor of any of Examples 1-7, further comprising a top shield plate mounted over the top surface of the substrate.

Example 9 includes the surface mount module form factor of any of Examples 1-8, wherein the land grid array pads are mapped to the castellated edge pads to provide a same-source subset of the land grid array pads.

Example 10 includes the surface mount module form factor of any of Examples 1- 9, wherein outer land grid array pads are mapped to the castellated edge pads with respective common pins.

Example 11 includes the surface mount module form factor of any of Examples 1-10, wherein the at least one electronic component comprises one or more of a processor, a memory device, or a communication device.

Example 12 includes a communication platform, comprising: a surface mount module form factor comprising: a substrate having a bottom surface, a top surface, and an outer periphery; a plurality of land grid array pads mounted on the bottom surface of the substrate; and a plurality of castellated edge pads mounted around the outer periphery of the substrate; wherein at least some of the land grid array pads are mapped to at least some of the castellated edge pads; and a plurality of electronic components mounted on the substrate; wherein the land grid array pads mapped to the castellated edge pads are coupled to the electronic components.

Example 13 includes the communication platform of Example 12, wherein one or more of the electronic components are mounted on the top surface of the substrate.

Example 14 includes the communication platform of any of Examples 12-13, further comprising a cavity in the bottom surface of the substrate, wherein one or more of the electronic components are mounted inside of the cavity.

Example 15 includes the communication platform of any of Examples 12-14, further comprising a top shield plate mounted over the top surface of the substrate.

Example 16 includes the communication platform of any of Examples 12-15, wherein the land grid array pads are mapped to the castellated edge pads to provide a same-source subset of the land grid array pads.

Example 17 includes the communication platform of any of Examples 12-16, wherein outer land grid array pads are mapped to the castellated edge pads with respective common pins.

Example 18 includes the communication platform of any of Examples 12-17, wherein the electronic components comprise a processor, a memory device, and a communication device.

A number of embodiments of the invention defined by the following claims have been described. Nevertheless, it will be understood that various modifications to the described embodiments may be made without departing from the scope of the claimed invention. Accordingly, other embodiments are within the scope of the following claims.

1. A surface mount module form factor, comprising:
a substrate having a bottom surface, a top surface, and an outer periphery with multiple edge portions;
at least one electronic component mounted on the substrate;
a plurality of land grid array pads mounted on the bottom surface of the substrate, the land grid array pads arranged to have an outermost set of land grid array pads that are adjacent to each of the edge portions, wherein at least some of the land grid array pads are coupled to the at least one electronic component; and
a plurality of castellated edge pads mounted around the outer periphery of the substrate along each of the edge portions, wherein at least some of the castellated edge pads are coupled to the at least one electronic component;
wherein at least some of the castellated edge pads are directly routed to a respective one of the outermost set of land grid array pads to provide same signal source subset mapping for the castellated edge pads and the respective one of the outermost set of land grid array pads.

2. The surface mount module form factor of claim 1, wherein the at least one electronic component comprises at least one single function component.

3. The surface mount module form factor of claim 1, wherein the at least one electronic component comprises at least one multi-function component.

4. The surface mount module form factor of claim 1, wherein the at least one electronic component comprises at least one system-on-module component.

5. The surface mount module form factor of claim 1, wherein the at least one electronic component is mounted on the top surface of the substrate.

6. The surface mount module form factor of claim 1, further comprising a cavity in the bottom surface of the substrate, wherein the at least one electronic component is mounted inside of the cavity.

7. The surface mount module form factor of claim 6, further comprising one or more additional electronic components mounted on the top surface of the substrate.

8. The surface mount module form factor of claim 1, further comprising a top shield plate mounted over the top surface of the substrate.

9. (canceled)

10. The surface mount module form factor of claim 1, wherein the castellated edge pads are directly routed to the respective outermost set of land grid array pads with respective common pins.

11. The surface mount module form factor of claim 1, wherein the at least one electronic component comprises one or more of a processor, a memory device, or a communication device.

12. A communication platform, comprising:
a surface mount module form factor, comprising:
a substrate having a bottom surface, a top surface, and an outer periphery with multiple edge portions;
a plurality of land grid array pads mounted on the bottom surface of the substrate, the land grid array pads arranged to have an outermost set of land grid array pads that are adjacent to each of the edge portions; and
a plurality of castellated edge pads mounted around the outer periphery of the substrate along each of the edge portions;
wherein at least some of the castellated edge pads are directly routed to a respective one of the outermost set of land grid array pads to provide same signal source subset mapping for the castellated edge pads and the respective one of the outermost set of land grid array pads; and
a plurality of electronic components mounted on the substrate;
wherein the castellated edge pads, directly routed to the respective outermost set of land grid array pads, are coupled to the electronic components.

13. The communication platform of claim 12, wherein one or more of the electronic components are mounted on the top surface of the substrate.

14. The communication platform of claim 12, further comprising a cavity in the bottom surface of the substrate, wherein one or more of the electronic components are mounted inside of the cavity.

15. The communication platform of claim 12, further comprising a top shield plate mounted over the top surface of the substrate.

16. (canceled)

17. The communication platform of claim 12, wherein the castellated edge pads are directly routed to the respective outermost set of land grid array pads with respective common pins.

18. The communication platform of claim 12, wherein the electronic components comprise a processor, a memory device, and a communication device.

19. The surface mount module form factor of claim 1, wherein the castellated edge pads wrap around the edge portions between the bottom and top surfaces of the substrate.

20. The surface mount module form factor of claim 1, wherein each of the castellated edge pads is directly routed to a respective one of the outermost set of land grid array pads.

21. The communication platform of claim 12, wherein the castellated edge pads wrap around the edge portions between the bottom and top surfaces of the substrate.

22. The communication platform of claim 12, wherein each of the castellated edge pads is directly routed to a respective one of the outermost set of land grid array pads.
